(19) United States
(12) Patent Application Publication
(10) Pub. No.: US 2024/0162104 A1
(43) Pub. Date: May 16, 2024

(54) SEMICONDUCTOR DEVICE, SEMICONDUCTOR PACKAGE, AND SEMICONDUCTOR CHIP MANUFACTURING METHOD

(71) Applicant: SAMSUNG ELECTRONICS CO., LTD., SUWON-SI (KR)

(72) Inventors: Hyunsu Hwang, Suwon-si (KR); Jumyong Park, Suwon-si (KR); Solji Song, Suwon-si (KR); Dongjoon Oh, Suwon-si (KR); Hyunchul Jung, Suwon-si (KR); Sanghoo Cho, Suwon-si (KR)

(21) Appl. No.: 18/462,010

(22) Filed: Sep. 6, 2023

(30) Foreign Application Priority Data
Nov. 15, 2022 (KR) 10-2022-0152817
May 9, 2023 (KR) 10-2023-0059671

(51) Int. Cl. H01L 23/31; H01L 21/78; H01L 23/00; H01L 23/522

(52) U.S. Cl. CPC H01L 23/3107; H01L 21/78; H01L 23/5226; H01L 24/08; H01L 2224/08145

(57) ABSTRACT

A semiconductor device may include a substrate, one or more front pads disposed on a front surface of the substrate, and a circuit layer including an insulating layer and at least one interconnection electrically connected to the one or more front pads. In some embodiments, the circuit layer may be disposed between the one or more front pads and the substrate. In some embodiments, a side surface of the circuit layer may include a burr that protrudes a height that is below a level of a front surface of the circuit layer. Additionally or alternatively, the burr may form a step portion in the circuit layer.

### CROSS-REFERENCE TO RELATED APPLICATION

This application claims the priority and benefit of Korean Patent Application Nos. 10-2022-0152817, filed on Nov. 15, 2022 and 10-2023-0059671, filed on May 9, 2023, with the Korean Intellectual Property Office, the inventive concepts of which are incorporated herein by reference.

### BACKGROUND

### 1. Field

The present inventive concept relates to a semiconductor device, a semiconductor package, and a method of manufacturing a semiconductor chip.

### 2. Description of Related Art

A semiconductor is a material with conductivity between a conductor and an insulator. Semiconductor materials are used in semiconductor devices and are used to create integrated circuits in an electronic device. Semiconductors are used in televisions, computers, tablets, and mobile phones to name a few applications.

The mass production of semiconductor devices has resulted in many refinements in the manufacturing process in order to meet business requirements and consumer demand requirements. For example, circuit patterns for use in semiconductor devices are also becoming finer in accordance with the demand for small and lightweight semiconductor devices. According to the trend for miniaturization and high performance of semiconductor packages, there is a demand for development of a system-in-package (SiP) technology for embedding a plurality of semiconductor chips performing different functions in a single package. In order to form fine interconnections connecting semiconductor chips within a single package, a technique of forming through-silicon vias (TSVs) and bonding semiconductor chips to each other through a bonding pad has been used. However, in some cases, improved bonding performance may be desired.

### SUMMARY

An aspect of the present disclosure provides a semiconductor device having improved electrical characteristics and/or reliability of a front surface, a semiconductor package having improved electrical characteristics and/or reliability between a plurality of semiconductor chips, and a method of manufacturing a semiconductor chip capable of improving electrical characteristics and/or reliability.

According to an aspect of the present disclosure, a semiconductor device may include: a substrate (e.g., a semiconductor substrate); one or more front pads disposed on a front surface of the substrate; and a circuit layer including an insulating layer and at least one interconnection electrically connected to the front pads, the insulating layer disposed between the front pads and the substrate, wherein a side surface of the circuit layer includes a burr, the burr protruding a height that is below a level of a front surface of the circuit layer, or the burr forming a step portion in the circuit layer, or a combination thereof.

According to an aspect of the present disclosure, an apparatus (e.g., a semiconductor package) may include: a plurality of semiconductor chips, wherein each of the semiconductor chips includes: a substrate; one or more front pads disposed on a front surface of the substrate; and a circuit layer including an insulating layer and at least one interconnection electrically connected to the front pads, the insulating layer disposed between the front pads and the substrate, wherein one of the plurality of semiconductor chips further includes a bonding insulating layer disposed on a front surface of the circuit layer and surrounding the one or more front pads, wherein the other of the plurality of semiconductor chips further include one or more rear pads disposed on a rear surface of the substrate and bonding insulating layers disposed on a rear surface of the substrate and surrounding the one or more rear pads, wherein the plurality of semiconductor chips are bonded to each other through the bonding insulating layers, and wherein a side surface of the circuit layer of at least one of the plurality of semiconductor chips may have a portion, the portion protruding while being spaced apart from the bonding insulating layer, or the portion forming a step portion in the circuit layer, or a combination thereof.

According to an aspect of the present disclosure, a method of manufacturing a semiconductor chip may include: forming a mask layer on a wafer, the wafer including a substrate and an insulating layer, etching, using a laser grooving process and a plasma process, a portion of the insulating layer so that the insulating layer is separated into a plurality of insulating layers; and etching a portion of the substrate so that the substrate is separated into a plurality of substrates, wherein etching the portion of the insulating layer may include performing the plasma process so that a burr according to the laser grooving process protrudes a height that is below a level of front surfaces of the plurality of insulating layers.

### BRIEF DESCRIPTION OF DRAWINGS

The above and other aspects, features, and advantages of the present disclosure will be more clearly understood from the following detailed description taken in conjunction with the accompanying drawings, in which:

FIG. 1 is a flowchart illustrating bonding between a plurality of semiconductor chips of a semiconductor package according to an example embodiment of the present disclosure;

FIG. 2 is a cross-sectional view illustrating bonding between a plurality of semiconductor chips of a semiconductor package according to an example embodiment of the present disclosure;

FIGS. 3A and 3B are plan views illustrating a scribe lane region ‘SL’ in a semiconductor wafer ‘WF’ according to an example embodiment of the present disclosure;

FIGS. 4A-4E are cross-sectional views illustrating a method of manufacturing a semiconductor chip according to an example embodiment of the present disclosure;

FIGS. 5A-5C are cross-sectional views illustrating a method of manufacturing a semiconductor chip according to an example embodiment of the present disclosure;

FIG. 6 is a cross-sectional view sequentially illustrating a method of manufacturing a semiconductor chip according to an example embodiment of the present disclosure;

FIGS. 7A-7F are cross-sectional views sequentially illustrating a method of manufacturing a semiconductor chip according to an example embodiment of the present disclosure;

FIG. 8 exemplarily illustrates a die to wafer bonding process according to an example embodiment of the present disclosure;

FIGS. 9A-9E are cross-sectional views illustrating a semiconductor device and a semiconductor package according to an example embodiment of the present disclosure; and

FIGS. 10A-10C are cross-sectional views illustrating a semiconductor device and a semiconductor package according to an example embodiment of the present disclosure.

### DETAILED DESCRIPTION

Semiconductor chips (e.g., integrated circuits (ICs), microchips, memory modules, microprocessors, etc.) may include electric circuits with many components (e.g., transistors, wiring, etc.) formed on a wafer (e.g., semiconductor wafer). The semiconductor chips may be essential components of electronic devices, enabling advances in communications, computing, healthcare, military systems, transportation, clean energy, and countless other applications.

In some cases, the manufacturing process of semiconductor chips may include first depositing (e.g., deposition process) a first layer (e.g., a thin film layer) on a wafer, where the first layer will form the wiring, transistors, and other components of the semiconductor chip. The wafer may be a thin slice of a semiconductor, such as a crystalline silicon (e.g., a disc-shaped piece of a silicon-based metal). Additionally, in some cases, the wafer may be referred to as a substrate. Subsequently, the first layer may be coated with a mask layer (e.g., photo mask, photo resist, etc.), where a circuit pattern can be projected on the mask layer. The manufacturing process may then include using the mask layer with the projected circuit pattern to process the first layer into the shape of the wiring, transistors, and other components of the semiconductor chip. In some cases, processing the first layer may include etching processes (e.g., laser grooving processes, plasma processes, etc.) and/or grinding processes to form the components of the semiconductor chip (e.g., on the wafer). For example, the etching processes may include forming grooves in the wafer or substrate.

However, when a groove is formed in the substrate (e.g., by a laser grooving process or another etching process), a burr protruding upwardly may be formed in an insulating layer of the substrate. In some cases, the burr formed in the insulating layer may deteriorate surface characteristics in an edge portion of individual semiconductor chips formed by wafer dicing and/or may provide an uneven bonding surface, thereby deteriorating bonding characteristics during bonding (e.g., bonding of individual semiconductor chips to each other).

According to aspects of the present disclosure, semiconductor chips may be manufactured based on lowering a level of a burr, thereby preventing the burr from substantially affecting a bonding surface of semiconductor chips (e.g., even if the burr is not removed). For example, a first method of lowering the level of the burr may include exposing the formed burr to a plasma etching process. Additionally or alternatively, a second method of lowering the level of the burr may include forming a trench on a side surface of the semiconductor chip and forming a burr in the trench.

The detailed description of the present disclosure refers to the accompanying drawings which, by way of example, illustrate specific embodiments in which the present disclosure may be practiced. These example embodiments are described in sufficient detail to enable one skilled in the art to practice the present disclosure. It should be understood that the various embodiments of the present disclosure are different from each other but are not necessarily mutually exclusive. For example, specific shapes, structures, and characteristics described herein may be implemented in one embodiment in another embodiment without departing from the spirit and scope of the present disclosure. Additionally, it should be understood that the location or arrangement of individual components within each disclosed embodiment may be changed without departing from the spirit and scope of the present disclosure. Accordingly, the detailed description set forth below is not to be taken in a limiting sense, and the scope of the present disclosure is limited only by the appended claims, along with all equivalents as claimed by those claims. Like reference numbers in the drawings indicate the same or similar function throughout the various aspects.

Hereinafter, embodiments of the present disclosure will be described in detail with reference to the accompanying drawings so that those skilled in the art can easily practice the present disclosure.

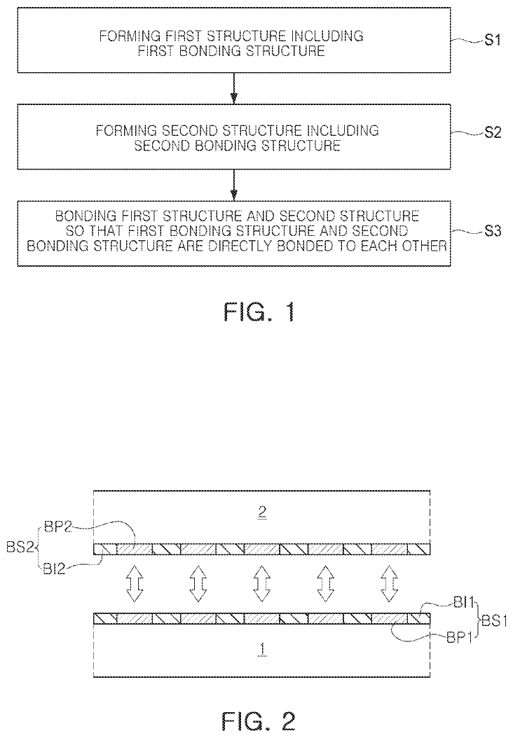

FIG. 1 is a flowchart illustrating bonding between a plurality of semiconductor chips of a semiconductor package according to an example embodiment of the present disclosure, and FIG. 2 is a cross-sectional view illustrating the bonding between the plurality of semiconductor chips of the semiconductor package according to an example embodiment of the present disclosure and as described with reference to FIG. 1.

Referring to FIGS. 1 and 2, as part of a first operation ‘S1,’ a first structure ‘1’ including a first bonding structure ‘BS1’ may be formed. Additionally, as part of a second operation ‘S2,’ a second structure ‘2’ including a second bonding structure ‘BS2’ may be formed. Subsequently, in some examples, at a third operation ‘S3,’ the first structure ‘1’ and the second structure ‘2’ may be bonded so that the first bonding structure ‘BS1’ and the second bonding structure ‘BS2’ directly contact with each other.

In some embodiments, the first bonding structure ‘BS1’ may include a first bonding pad ‘BP1’ and a first bonding insulating layer ‘BI1,’ where the first bonding insulating layer ‘BI1’ surrounds at least a portion of a side surface of the first bonding pad ‘BP1.’ Additionally, the second bonding surface ‘BS2’ may include a second bonding pad ‘BP2’ and a second bonding insulating layer ‘BI2,’ where the second bonding insulating layer ‘BI2’ surrounds at least a portion of a side surface of the second bonding pad ‘BP2.’ In some embodiments, the first bonding pad ‘BP1’ and the second bonding pad ‘BP2’ may contact each other and may be bonded together through a first bonding operation (e.g., through copper-to-copper bonding). Additionally or alternatively, the first bonding insulating layer ‘BI1’ and the second bonding insulating layer ‘BI2’ may contact each other and may be bonded through a second bonding operation (e.g., dielectric-to-dielectric bonding). In some embodiments, the first bonding structure ‘BS1’ and the second bonding structure ‘BS2’ may be electrically connected to a redistribution layer or a through-via disposed on each of the first structure ‘1’ and the second structure ‘2.’

In some embodiments, bonding of the first structure ‘1’ and the second structure ‘2’ may include die-to-die bonding, die-to-wafer bonding, and/or wafer-to-wafer bonding. For example, when each of the first structure ‘1’ and the second structure ‘2’ is a semiconductor chip, bonding of the first structure ‘1’ and the second structure ‘2’ may be die-to-die bonding. Additionally or alternatively, when the first structure ‘1’ is one of a plurality of semiconductor structures divided into scribe lanes on a semiconductor wafer and the second structure ‘2’ is a semiconductor chip disposed above each of the plurality of semiconductor structures, bonding of the first structure ‘1’ and the second structure ‘2’ may be die-to-wafer bonding. Additionally or alternatively, when the first structure ‘1’ and the second structure ‘2’ are one of a plurality of semiconductor structures divided into scribe lanes in each of the first semiconductor wafer and the second semiconductor wafer, bonding of the first structure ‘1’ and the second structure ‘2’ may be wafer-to-wafer bonding.

According to an embodiment of the present disclosure, during a laser grooving process, a burr may be formed on the insulating layer. In some embodiments, the burr may not cause irregularities in at least one of the first bonding structure ‘BS1’ and the second bonding structure ‘BS2.’ Accordingly, electrical characteristics and reliability of a front surface of a semiconductor chip (e.g., which may correspond to one of the first and second structures ‘1‘and’2’) may be improved, and electrical characteristics and reliability between a plurality of semiconductor chips (e.g., which may correspond to the first and second structures ‘1‘ and’2’) may be improved.

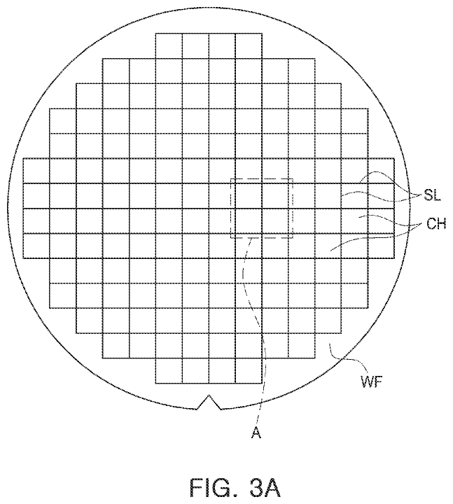

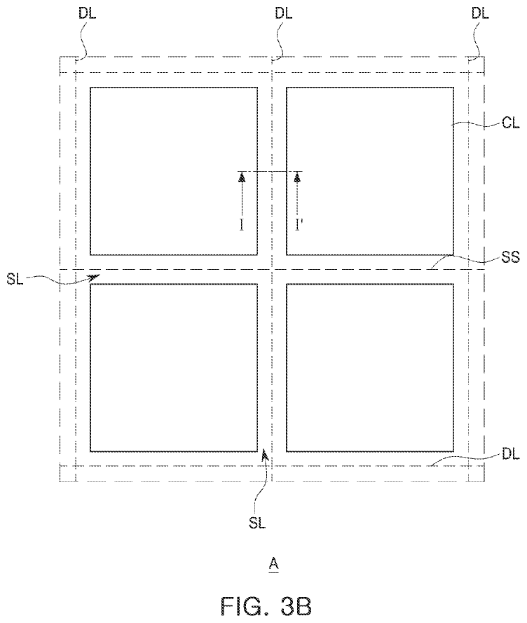

FIGS. 3A and 3B are plan views illustrating a scribe lane region ‘SL’ in a semiconductor wafer ‘WF,’ and FIG. 3B is an enlarged view of a region ‘A’ of the scribe lane region ‘SL’ in the semiconductor wafer ‘WF’ as described with reference to FIG. 3A. In some examples, the scribe lane region ‘SL’ in the semiconductor wafer ‘WF’ as described with reference to FIGS. 3A and 3B may implement aspects of or may be implemented by aspects as described with reference to FIGS. 1 and 2.

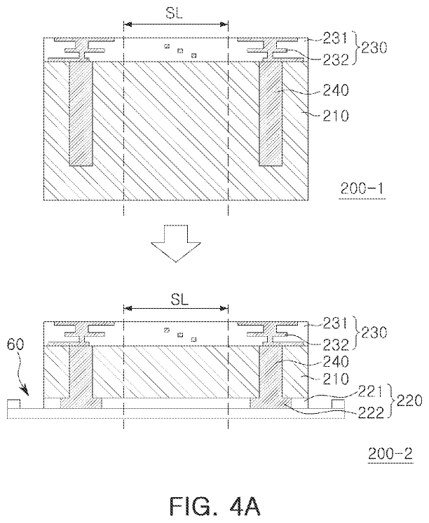

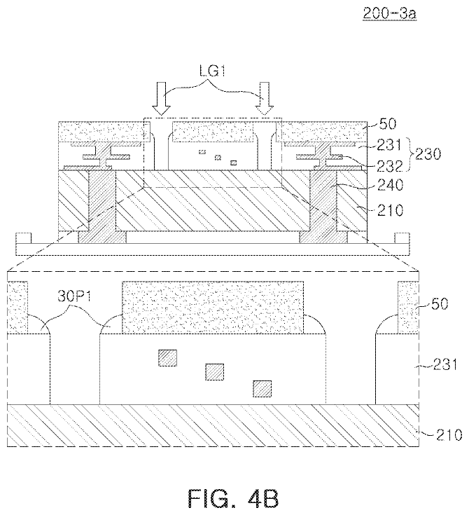

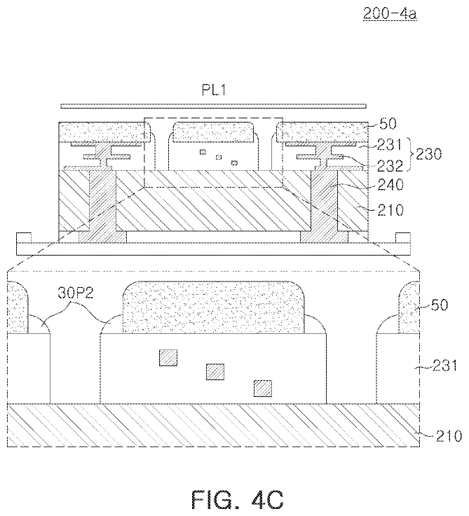

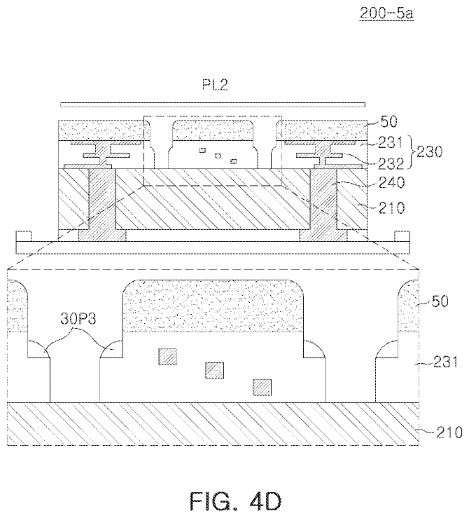

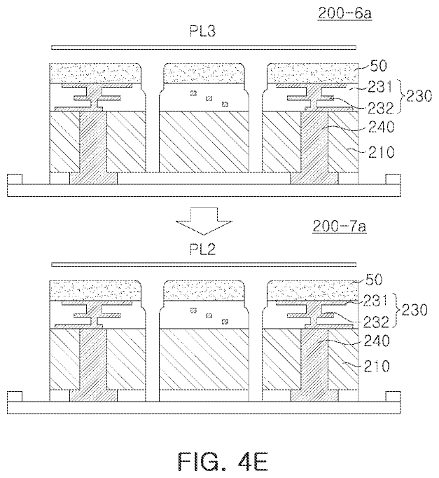

Referring to FIGS. 3A and 3B, the semiconductor wafer ‘WF’ may be prepared, where the semiconductor wafer ‘WF’ includes a plurality of chip regions ‘CH’ and a plurality of scribe lane regions ‘SL.’ Additionally, the plurality of scribe lane regions ‘SL’ may be located between the plurality of chip regions ‘CH.’. In some embodiments, the semiconductor wafer ‘WF’ may be a semiconductor wafer before performing dicing. As illustrated in the example of FIG. 3B, the plurality of scribe lane regions ‘SL’ may include a region through which one or more dicing line(s) ‘DL’ passes. In some examples, the dicing line(s) ‘DL’ may be arbitrary line(s). Through a dicing process to be described later, the semiconductor wafer ‘WF’ may be cut along the dicing line(s) ‘DL.’ In some embodiments, the semiconductor wafer ‘WF’ may include a substrate 210 and a circuit layer 230 as will be described with reference to FIGS. 4A-7F.

FIGS. 4A-4E are cross-sectional views sequentially illustrating a method of manufacturing a semiconductor chip according to an example embodiment of the present disclosure. Additionally, FIGS. 4A-4E may illustrate a process in which a semiconductor wafer is diced in a cross-section and is formed into a plurality of semiconductor chips. For example, the semiconductor wafer may be diced in a cross-section along a cutting line I-I′ as illustrated in the example of FIG. 3B. In some examples, the cross-sectional views sequentially illustrating the method of manufacturing a semiconductor chip as illustrated in the examples of FIGS. 4A-4E may implement aspects of or may be implemented by aspects as described with reference to FIGS. 1-3B.

Referring to FIG. 4A, a semiconductor chip 200-1 in a first state according to an example embodiment of the present disclosure may have a structure in which a substrate 210 and a circuit layer 230 are stacked.

The substrate 210 may include semiconductor elements (e.g., silicon (Si), germanium (Ge), etc.) or compound semiconductors (e.g., silicon carbide (SiC), gallium arsenide (GaAs), indium arsenide (InAs), indium phosphide (InP), etc.). Additionally, the substrate 210 may optionally include a through-via 240.

In some embodiments, a device layer may be formed between the substrate 210 and the circuit layer 230, and the device layer may include transistors forming at least part of an integrated circuit. The transistors forming at least part of the integrated circuit may include a field-effect transistor (FET), a planar metal oxide semiconductor FET (MOSFET), a FinFET (e.g., a FET having a fin structure in an active region thereof), a Multi Bridge Channel FET (MBCFET™) (e.g., including a plurality of channels vertically stacked on the active region), a gate-all-around transistor, or a vertical FET (VFET), but the present inventive concept is not limited thereto. Additionally, the integrated circuit may include a volatile memory device (e.g., dynamic random-access memory (DRAM), static random-access memory (SRAM), etc.) and/or a non-volatile memory device (e.g., parallel random-access machine (PRAM), magnetoresistive random-access memory (MRAM), resistive random-access memory (ReRAM), a flash memory device, etc.).

In some embodiments, the circuit layer 230 may include an insulating layer 231 and an interconnection 232, and the interconnection 232 may be electrically connected to the integrated circuit of the device layer. In a scribe lane region ‘SL,’ an align-key provided for aligning a photo mask (e.g., during a photolithography process) may be provided within the substrate 210 or the insulating layer 231. In some embodiments, the insulating layer 231 may be formed of at least one of silicon oxide (SiO), silicon nitride (SiN), silicon oxynitride (SiON), silicon oxycarbide (SiOC), silicon carbonitride (SiCN), or a combination thereof. Additionally, the interconnection 232 and/or the through-via 240 may include a metal material, such as aluminum (Al), gold (Au), cobalt (Co), copper (Cu), nickel (Ni), lead (Pb), tantalum (Ta), tellurium (Te), titanium (Ti), tungsten (W), or a combination thereof. In some embodiments, a barrier film (not shown) may be disposed between the interconnection 232 and the insulating layer 231 or between the through-via 240 and the substrate 210. The barrier film may include a metal material, such as Ti, titanium nitride (TiN), Ta, tantalum nitride (TaN), or a combination thereof.

Referring to FIG. 4A, a second chip 200-2 in a second state according to an example embodiment of the present disclosure is illustrated. In some embodiments, the second chip 200-2 in the second state may include a structure in which a bonding structure 220 is formed. For example, the bonding structure 220 may be formed on a lower surface of a structure that is formed based on a grinding process where a lower portion of the semiconductor chip 200-1 in the first state is ground. Additionally or alternatively, in some embodiments, the second chip 200-2 in the second state may include a structure in which the structure is disposed on a carrier 60.

In some embodiments, the bonding structure 220 may include a bonding insulating layer 221 and one or more rear pads 222. In some examples, the bonding insulating layer 221 may include at least one of SiO, SiN, SiON, silicon carbide (SiC), SiOC, and SiCN. Additionally, the rear pads 222 may include at least one of Cu, Ni, Au, and silver (Ag), or alloys thereof. In some embodiments, a dielectric film (e.g., an ONO layer) may be disposed between the substrate 210 and the bonding insulating layer 221. For example, the dielectric film may electrically insulate the rear pads 222 from a semiconductor material of the substrate 110.

Referring to FIGS. 4B-44D, the method of manufacturing a semiconductor chip according to an example embodiment of the present disclosure may include: forming a mask layer 50 on a wafer, where the wafer includes at least a substrate 210 and an insulating layer 231; and etching a portion of the insulating layer 231 (e.g., edges of a scribe lane region) so that the insulating layer 231 is separated into a plurality of insulating layers using a laser grooving process ‘LG1’ and plasma processes ‘PL1’ and ‘PL2.’ Accordingly, a semiconductor chip 200-3a in a third state (e.g., based on the laser grooving process ‘LG1’), a semiconductor chip 200-4a in a fourth state (e.g., based on the plasma process ‘PL1’), and a semiconductor chip 200-5a in a fifth state (e.g., based on the plasma process ‘PL2’) according to an example embodiment of the present disclosure may be manufactured.

Referring to FIG. 4B, a mask layer 50 may be formed on a front surface of the semiconductor wafer. In some embodiments, the mask layer 50 may be formed of a photosensitive material, such as photo resist or a non-photosensitive material (e.g., a Protection Layer Coating (PLC)).

Referring to FIG. 4B, a portion of the mask layer 50 and a portion of the insulating layer 231 may be removed based on a laser grooving process ‘LG1.’ For example, the laser grooving process ‘LG1’ may include a process of irradiating a laser beam downwardly from an upper surface of the mask layer 50 (e.g., to remove the portion of the mask layer 50 and the portion of the insulating layer 231). In some embodiments, a width of a portion of the mask layer 50 may be greater than a width of a portion of the insulating layer 231. For example, a difference in width may be implemented using the laser grooving process ‘LG1’ based on a difference in frequency or average output of a laser beam and/or a difference in scan speed or the number of scan repetitions of a laser beam in a horizontal direction thereof.

As described herein, a portion of the insulating layer 231 removed by the laser grooving process ‘LG1’ may be derived as one or more burrs 30P1 at an edge of the insulating layer 231. In some embodiments, the burr(s) 30P1 may convexly protrude beyond an upper surface of the insulating layer 231. In some examples, the burr(s) 30P1 (e.g., protruding beyond the upper surface of the insulating layer 231) may deteriorate surface characteristics of individual semiconductor chips after dicing. For example, in a process or bonding between a first structure ‘1’ and a second structure ‘2’ (e.g., as illustrated in FIG. 2), an uneven bonding surface may be provided, so that bonding characteristics may be deteriorated. In some embodiments, the burr 30P1 may have a height of about 2 micrometers (μm) or less and a maximum width of about 10 μm or less, and a density of the burr 30P1 may be lower than that of the insulating layer 231.

Referring to FIG. 4C, the plasma process ‘PL1’ may be a first plasma process using an O2 plasma gas. In some examples, the plasma process ‘PL1’ may be a pretreatment for removing fine particles of the mask layer 50 that may remain in a burr 30P2. Additionally, the plasma process ‘PL1’ may polish an edge of the mask layer 50.

Referring to FIG. 4D, the plasma process ‘PL2’ may be a second plasma process using a CxFy or CHxFy plasma gas. In some embodiments, by performing isotropic etching on the burr 30P2 of FIG. 4C, a position of a burr 30P3 may be further lowered.

As described herein, the burr 30P3 may protrude so as not to exceed an upper surface of the insulating layer 231, or the burr 30P3 may form a step portion in the insulating layer 231 (e.g., or additional portion of the circuit layer 230). For example, the burr 30P3 may protrude a height that is below the upper surface of the insulating layer 231. Accordingly, based on the burr 30P3 not exceeding the upper surface of the insulating layer 231 or forming a step portion, the burr 30P3 may not deteriorate surface characteristics of individual semiconductor chips after dicing. For example, as illustrated in FIG. 2, in a process of bonding the first structure ‘1’ and the second structure ‘2,’ a substantially flat bonding surface may be provided so that bonding characteristics may be improved. Here. ‘x’ and ‘y’ of CxFy and CHxFy may be natural numbers. For example, CxFy may be C4F8 or C4F6, and CHxFy may be CH2F2. Accordingly, etching a portion of the insulating layer 231 (e.g., as part of the method of manufacturing a semiconductor chip according to an example embodiment of the present disclosure) may include performing a plasma process ‘PL2’ so that the burr 30P3 (e.g., produced from the laser grooving process ‘LG1’) does not exceed a level of front surfaces of the plurality of insulating layers 231.

Referring to FIG. 4E, the method of manufacturing a semiconductor chip according to an example embodiment of the present disclosure may include etching a portion of a substrate 210 (e.g., edges of a scribe lane region) so that the substrate 210 is separated into a plurality of substrates. Accordingly, a semiconductor chip 200-6a in a sixth state and a semiconductor chip 200-7a in a seventh state according to an example embodiment of the present disclosure may be manufactured.

For example, the semiconductor chip 200-6a in the sixth state may include a third plasma process ‘PL3.’ In some embodiments, the third plasma process ‘PL3’ may include the substrate 210 being separated into a plurality of substrates by repeatedly and alternately using a plasma gas (e.g., sulfur hexafluoride (SF6) plasma gas, octafluorocyclobutane (C4F8) plasma gas, etc.). Additionally or alternatively, with the semiconductor chip 200-7a in the seventh state, in a second plasma process ‘PL2,’ a bonding insulating layer may be separated into a plurality of bonding insulating layers by etching a portion of the bonding insulating layer.

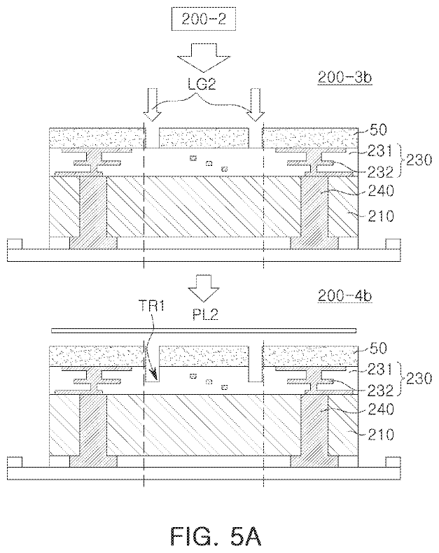

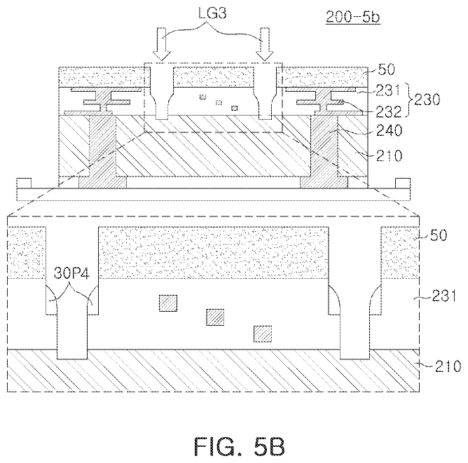

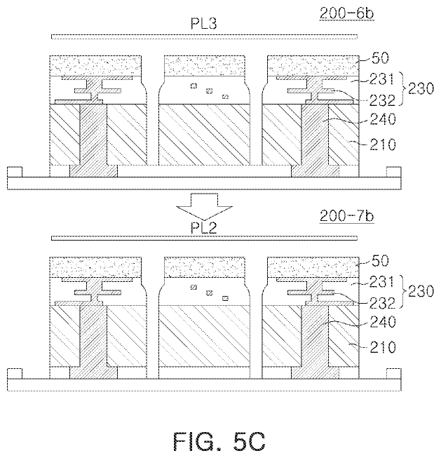

FIGS. 5A-5C are cross-sectional views sequentially illustrating a method of manufacturing a semiconductor chip according to an example embodiment of the present disclosure. In some examples, the cross-sectional views sequentially illustrating the method of manufacturing a semiconductor chip may implement aspects of or may be implemented by aspects as described with reference to FIGS. 1-4E.

Referring to FIG. 5A, a portion of the mask layer 50 of the semiconductor chip 200-2 in the second state (e.g., as described with reference to FIG. 4A) may be removed without removing a portion of the insulating layer 231 based on a laser grooving process ‘LG2.’ For example, the laser grooving process ‘LG2’ may include a process of irradiating a laser beam downwardly onto an upper surface of the semiconductor chip 200-2 in the second state to remove the portion of the mask layer 50 but not remove the portion of the insulating layer 231. Thereafter, in a plasma process ‘PL2,’ a trench ‘TR1’ may be formed in the insulating layer 231 using a plasma gas (e.g., a CxFy plasma gas, a CHxFy plasma gas, etc.). Accordingly, a semiconductor chip 200-3b in a third state (e.g., based on the laser grooving process ‘LG2’) and a semiconductor chip 200-4b in a fourth state (e.g., based on the plasma process ‘PL2’) according to an example embodiment of the present disclosure may be manufactured.

Referring to FIG. 5B, a semiconductor chip 200-5b in a fifth state according to an example embodiment of the present disclosure may be manufactured. In some embodiments, the semiconductor chip 200-5b in the fifth state may include a portion of the insulating layer 231 (e.g., of the semiconductor chip 200-4b in the fourth state) being removed. For example, the portion of the insulating layer 231 may be removed based on a laser grooving process ‘LG3.’. Subsequently, in some embodiments, one or more burrs 30P4 may be formed on the trench ‘TR1’ as illustrated in FIG. 5A (e.g., after performing the laser grooving process ‘LG3’).

Based on an upper surface of the trench ‘TR1’ being positioned lower than an upper surface of the insulating layer 231, the burr 30P4 may protrude so as not to exceed the upper surface of the insulating layer 231, or the burr 30P4 may form a step portion. For example, the burr 30P4 may protrude a height that is below the upper surface of the insulating layer 231. Additionally or alternatively, the burr 30P4 may be disposed on a step portion (e.g., a portion of the trench ‘TR1’) of a side surface of the circuit layer 230 or may form a step portion. In some embodiments, the step portion (e.g., the portion of the trench ‘TR1’) of the side surface of the circuit layer 230 may provide an additional front surface (e.g., front surface). Additionally, the burr 30P4 may protrude convexly from the additional front surface. In some embodiments, the burr 30P4 may contain a mixed material in which at least one of a material of the interconnection 232 and a material of the substrate 210 is mixed with an insulating material of the insulating layer 231.

In some embodiments, the method of manufacturing a semiconductor chip according to an example embodiment of the present disclosure may include an operation of etching a portion of the insulating layer 231 based on performing a plasma process ‘PL2’ so that the burr 30P4 (e.g., produced based on a laser grooving process ‘LG3’) does not exceed a level of front surfaces of the plurality of insulating layers 231. In such embodiments, the laser grooving process ‘LG3’ may be performed after the plasma process ‘PL2.’

Referring to FIG. 5C, a semiconductor chip 200-6b in a sixth state and a semiconductor chip 200-7b in a seventh state according to an example embodiment of the present disclosure may be manufactured based on an operation of etching a portion (e.g., edges of a scribe lane region) of the substrate 210 (e.g., based on the plasma process ‘PL3’) and a portion of the bonding insulating layer (e.g., based on the plasma process ‘PL2’) so that the substrate 210 is separated into a plurality of substrates.

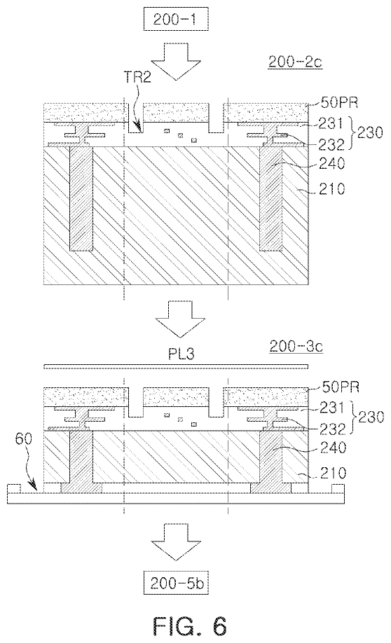

FIG. 6 is a cross-sectional view sequentially illustrating a method of manufacturing a semiconductor chip according to an example embodiment of the present disclosure. In some examples, the cross-sectional view sequentially illustrating the method of manufacturing a semiconductor chip may implement aspects of or may be implemented by aspects as described with reference to FIGS. 1-5C.

Referring to FIG. 6, a semiconductor chip 200-2c in a second state according to an example embodiment of the present disclosure may be manufactured. For example, in some embodiments, the semiconductor chip 200-2c in the second state may include a first mask layer 50PR that is formed on an upper surface of the semiconductor chip 200-1 in the first state as described with reference to FIG. 4A. Additionally, based on a plasma process ‘PL2’ (e.g., using a CxFy or CHxFy plasma gas), the semiconductor chip 200-2c in the second state may include a trench ‘TR2’ in an insulating layer 231. That is, the plasma process ‘PL2’ may include forming a trench in the insulating layer 231 (e.g., of the semiconductor chip 200-1 in the first state as described with reference to FIG. 4A) using a CxFy or CHxFy plasma gas in a state in which the first mask layer 50PR is formed. In some embodiments, a portion of the first mask layer 50PR (e.g., a portion vertically overlapping the trench ‘TR2’) may be removed by a plasma process ‘PL2’ or a laser grooving process.

In some embodiments, a lower portion of the semiconductor chip 200-2c in the second state may be ground by a grinding process to produce a semiconductor chip 200-3c in a third state. Subsequently, the semiconductor chip 200-3c in the third state may include a structure in which a bonding structure is formed on a lower surface of the structure based on the grinding process. Additionally, the semiconductor chip 200-3c in the third state may have a structure in which the structure is disposed on a carrier 60.

Subsequently, in some embodiments, the first mask layer 50PR may be removed, and as a second mask layer (e.g., corresponding to the mask layer 50 as described with reference to FIG. 5B) is formed, the semiconductor chip 200-5b in the fifth state as described with reference to FIG. 5B may be manufactured. In some embodiments, the first mask layer 50PR may be formed of a photosensitive material (e.g., such as photo resist), and the second mask layer may be formed of a non-photosensitive material (e.g., such as PLC).

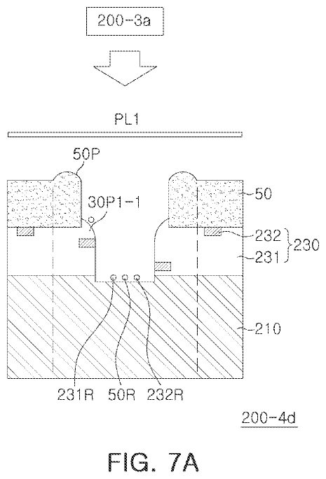

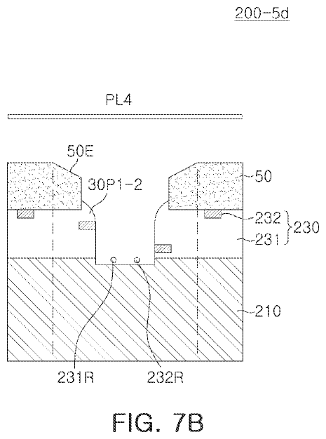

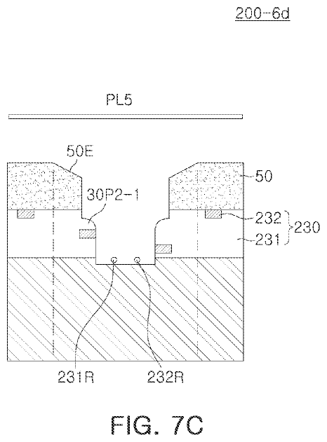

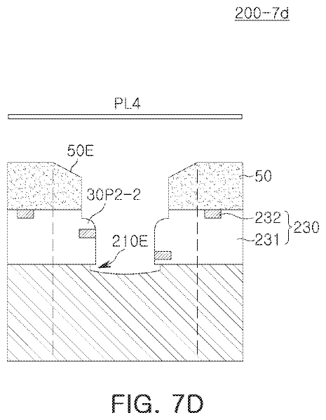

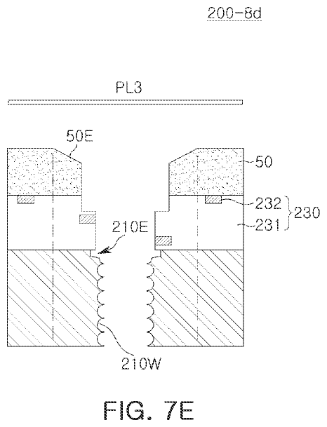

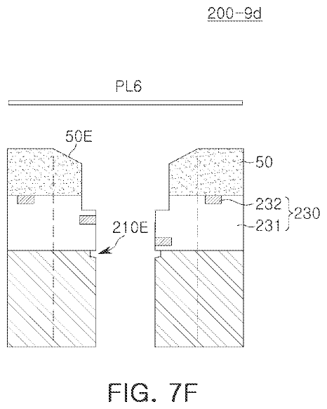

FIGS. 7A-7F are cross-sectional views sequentially illustrating a method of manufacturing a semiconductor chip according to an example embodiment of the present disclosure. In some examples, the cross-sectional views sequentially illustrating the method of manufacturing a semiconductor chip may implement aspects of or may be implemented by aspects as described with reference to FIGS. 1-6.

Referring to FIG. 7A, a semiconductor chip 200-4d in a fourth state may be manufactured according to an example embodiment of the present disclosure. In some embodiments, the semiconductor chip 200-4d in the fourth state may represent the semiconductor chip 200-3a in the third state (e.g., as described with reference to FIG. 4B) in which fine particles 231R of the insulating layer 231, fine particles 232R of the interconnection 232, and/or fine particles 50R of the mask layer 50 remain. Additionally, in some embodiments, a plasma process ‘PL1’ may be performed on the semiconductor chip 200-4d in the fourth state. For example, the plasma process ‘PL1’ may be a first plasma process (e.g., using O2 plasma gas). Based on the plasma process ‘PL1,’ the fine particles 50R may be removed, and a material of the mask layer 50 mixed with a burr 30P1-1 may also be removed. In some examples, the plasma process ‘PL1’ may be referred to as a descum process. For the plasma process ‘PL1,’ one of a variety of plasma gases (e.g., N₂ plasma gas, Ar plasma gas, O2 plasma gas, etc.) according to design may be used.

In some embodiments, the mask layer 50 may have a mask burr 50P formed by the laser grooving process ‘LG1’ as described with reference to FIG. 4B. Additionally or alternatively, the mask burr 50P may be removed by the plasma process ‘PL1’ and may be derived as an extension portion 50E.

Referring to FIG. 7B, a semiconductor chip 200-5d in a fifth state may be manufactured according to an example embodiment of the present disclosure. In some embodiments, the semiconductor chip 200-5d in the fifth state may include a plasma process ‘PL4.’ Based on the plasma process ‘PL4,’ a position of a burr 30P1-2 may be disposed further downwardly (e.g., such as a burr 30P2-1 as will be described with reference to FIG. 7C). In some embodiments, the plasma process ‘PL4’ may use CxFy plasma gas. For example, the CxFy plasma gas may be CF4.

Referring to FIGS. 7C and 7D, a plasma process ‘PL5’ may be performed on a semiconductor chip 200-6d in a sixth state. Based on the plasma process ‘PL5,’ fine particles 231R of the insulating layer 231 and fine particles 232R of the interconnection 232 of the semiconductor chip 200-6d in the sixth state may be removed. Additionally, in some embodiments, a substrate of a semiconductor chip 200-7d in a seventh state as described with reference to FIG. 7D may have a recessed portion 210E. For example, the recessed portion 210E may be recessed between the substrate and the circuit layer 230. In some embodiments, the plasma process ‘PL5’ may use SF6 plasma gas and may have an isotropic etching characteristic, which may result in the recessed portion 210E being formed. The recessed portion 210E may be expressed as an undercut.

Referring to FIG. 7E, a semiconductor chip 200-8d in an eighth state may be manufactured according to an example embodiment of the present disclosure. For example, the semiconductor chip 200-8d in the eighth state may include a plasma process ‘PL3.’ In some embodiments, based on the plasma process ‘PL3,’ a portion of the substrate may be removed, and the substrate may be separated into a plurality of substrates by alternately and repeatedly using a plasma gas (e.g., SF6 plasma gas, C4F8 plasma gas, etc.). Subsequently, in some embodiments, a side surface of the substrate may have an uneven side surface 210W.

Referring to FIG. 7F, a semiconductor chip 200-9d in a ninth state can be manufactured according to an example embodiment of the present disclosure. For example, the semiconductor chip 200-9d in the ninth state may include a plasma process ‘PL6.’ In some embodiments, based on the plasma process ‘PL6,’ the uneven side surface 210W (e.g., as described with reference to FIG. 7E) may be removed. In some examples, the plasma process ‘PL6’ may use a nitrogen trifluoride (NF3) plasma gas.

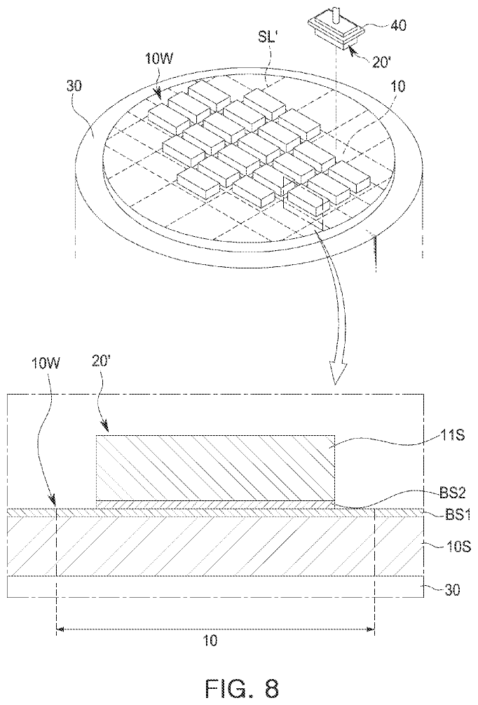

FIG. 8 illustrates a die-to-wafer bonding process. In some examples, the die-to-wafer bonding process as described with reference to FIG. 8 may implement aspects of or may be implemented by aspects as described with reference to FIGS. 1-7F. For example, the die-to-wafer bonding process may illustrate a process of bonding semiconductor chips to a wafer, where the semiconductor chips are manufactured based on techniques and methods as described with reference to FIGS. 3A to 7F.

Referring to FIG. 8, a semiconductor chip 20′ may be pre-bonded on a wafer structure 10W. In some embodiments, the wafer structure 10W may include a plurality of semiconductor structures 10 that are formed on an electrostatic chuck 30 using a pick-and-place device 40. Additionally, the wafer structure 10W may include the semiconductor structures 10 divided into scribe lanes SL′. In some embodiments, the semiconductor structures 10 may include a first substrate structure 10S and a first bonding structure ‘BS1’ on the first substrate structure 10S. Additionally, the semiconductor chip 20′ may include a bonding pad and may be directly disposed on the semiconductor structures 10. In some examples, “pre-bonding” may be understood as placing the semiconductor chip 20′ on the corresponding semiconductor structure 10 without applying pressure or heat. Subsequently, in some embodiments, the semiconductor chip 20′ and the semiconductor structure 10 may be bonded to each other (e.g., by performing dielectric-dielectric bonding and copper-copper bonding). As illustrated in the enlarged cross-sectional view of FIG. 8, the semiconductor chip 20′ may include a second bonding structure ‘BS2’ that includes an insulating layer with burrs spaced apart and a second substrate structure 11S on the second bonding structure ‘BS2.’ (e.g., as described with reference to FIGS. 4A-7F). In some embodiments, the second bonding structure ‘BS2’ of the semiconductor chip 20′ may provide a substantially flat surface without irregularities. Accordingly, bonding characteristics with the semiconductor structure 10 may be improved.

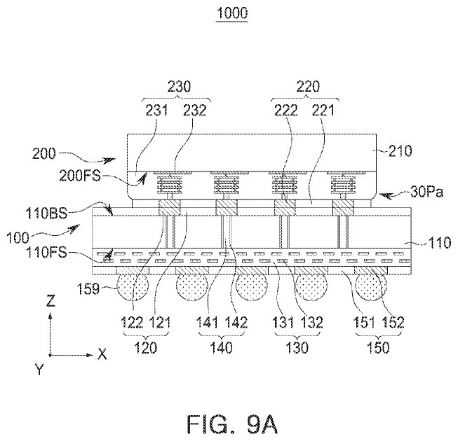

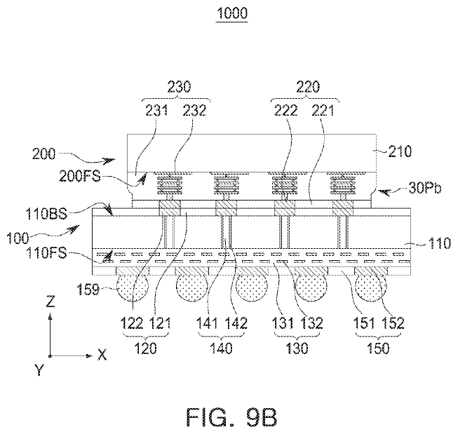

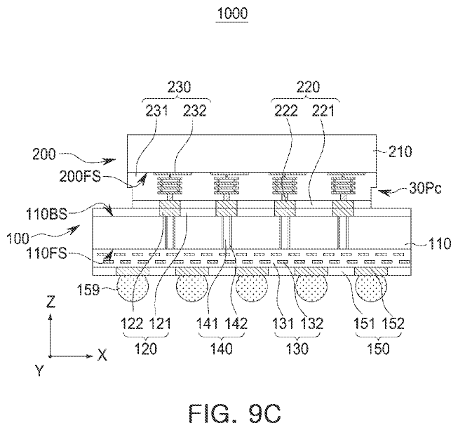

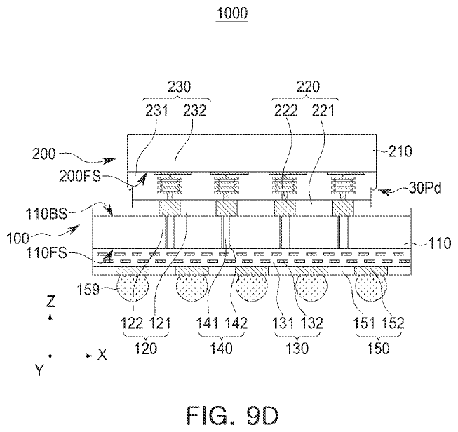

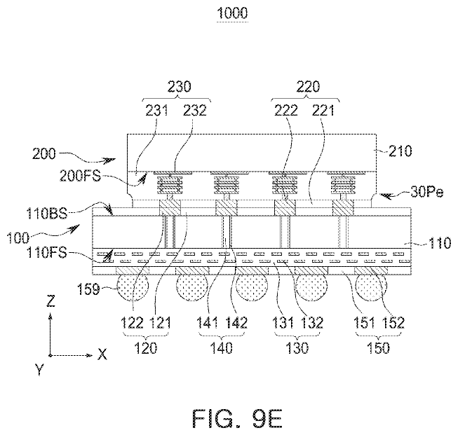

FIGS. 9A-9E are cross-sectional views illustrating a semiconductor device and a semiconductor package according to an example embodiment of the present disclosure. In some examples, the cross-sectional views illustrating a semiconductor device and a semiconductor package as described with reference to FIGS. 9A-9E may implement aspects of or may be implemented by aspects as described with reference to FIGS. 1-8.

Referring to FIGS. 9A-9E, a semiconductor package 1000 according to an example embodiment of the present disclosure may include a semiconductor chip 200 according to an example embodiment of the present disclosure. In some embodiments, the semiconductor package 1000 may include a structure in which a semiconductor chip 200 and a semiconductor structure 100 are bonded. The semiconductor structure 100 may be a semiconductor chip. A side surface of a circuit layer 230 of the semiconductor chip 200 according to example embodiment of the present disclosure may include burrs 30Pa, 30Pb, 30Pc, 30Pd, and 30Pe protruding so as not to exceed a level of a front surface (e.g., a lower surface) of the circuit layer 230 or forming a step portion. Additionally or alternatively, the burrs 30Pa, 30Pb, 30Pc, 30Pd, and 30Pe may be spaced apart from bonding insulating layers 121 and 221. In some embodiments, the bonding insulating layers 121 and 221 may provide a substantially flat surface without irregularities, thereby improving bonding characteristics between the semiconductor chip 200 and the semiconductor structure 100 and improving electrical characteristics and reliability between the semiconductor chip 200 and the semiconductor structure 100.

Referring to FIGS. 9A-9E, the burrs 30Pa, 30Pb, 30Pc, 30Pd, and 30Pe may have a more gentle slope on a side surface of the circuit layer 230 than in a region in which the burrs 30Pa, 30Pb, 30Pc, 30Pd, and 30Pe are not disposed. Referring to FIG. 9A, the burr 30Pa may be formed closest to an edge of the front surface (e.g., lower surface) of the circuit layer 230.

Referring to FIGS. 9B-9E, the circuit layer 230 may include a first edge between the front surface (e.g., lower surface) and the side surface of the circuit layer 230 and may include a second edge formed by the burrs 30Pb, 30Pc, 30Pd, and 30Pe. In some embodiments, as illustrated in the examples of FIGS. 9B and 9D, the second edge formed by the burrs 30Pb and 30Pd may be more curved than the first edge.

In some embodiments, as illustrated in the example of FIG. 9C, the burr 30Pc may have a substantially angular shape. Additionally or alternatively, as illustrated in the example of FIG. 9D, the burr 30Pd may have a recessed shape. Additionally or alternatively, as illustrated in the example of FIG. 9C, the burr 30Pe may have a concave shape.

Referring to FIGS. 9A-9E, the semiconductor package 1000 according to an example embodiment may include a semiconductor structure 100 and a semiconductor chip 200 stacked in a vertical direction (e.g., Z-axis direction). In some embodiments, the semiconductor structure 100 and the semiconductor chip 200 may have a structure in which elements exposed on an upper surface of the semiconductor structures 100 and a lower surface of the semiconductor chip 200 are directly bonded (e.g., referred to as hybrid bonding, direct bonding, or the like) without a separate connection member (e.g., metal pillar, solder bump, or the like). For example, dielectric-to-dielectric bonding and copper-to-copper bonding may be formed at an interface between the semiconductor structure 100 and the semiconductor chip 200. In some embodiments, a first bonding structure 120 of the semiconductor structure 100 and a second bonding structure 220 of the semiconductor chip 200 may be bonded and bonded to each other.

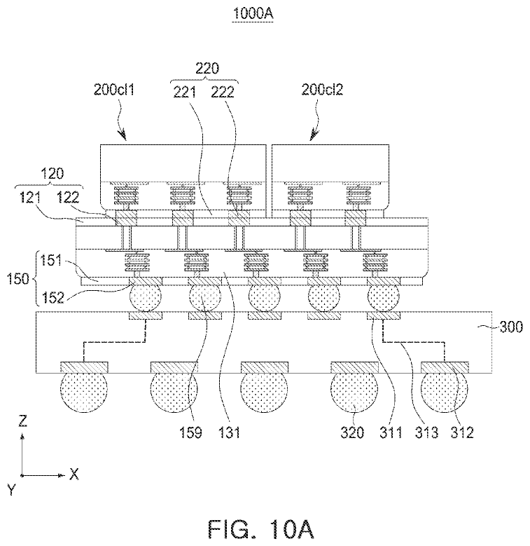

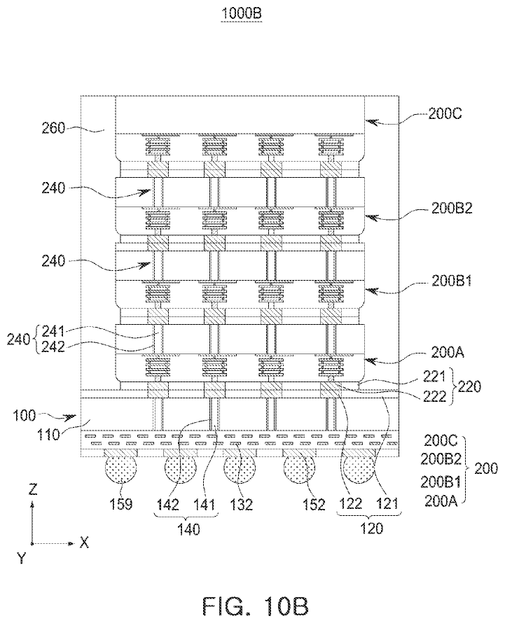

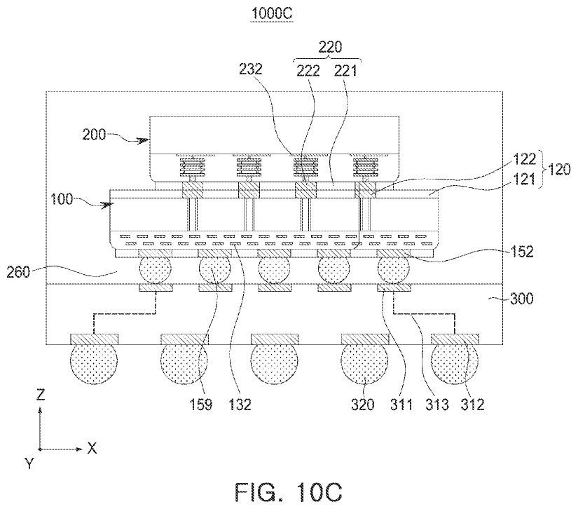

The semiconductor structure 100 may be a semiconductor wafer-based structure and may include a substrate 110, a rear cover layer 120 (e.g., as a ‘first bonding structure’), a circuit layer 130, a through-via 140, and a front cover layer 150. In some embodiments, the semiconductor structure 100 may be a silicon interposer substrate, a semiconductor chip, or the like. When the semiconductor structure 100 is a semiconductor chip, the semiconductor structure 100 and the semiconductor chip 200 stacked thereon may be chiplets constituting a multi-chip module (MCM), but the present disclosure is not limited thereto. This will be described later with reference to FIGS. 10A-10C.

The substrate 110 may include semiconductor elements (e.g., Si, Ge, etc.) and/or compound semiconductors (e.g., SiC, GaAs, InAs, InP, etc.). In some embodiments, the substrate 110 may be a part of a semiconductor wafer and may be provided as an individual substrate 110 by cutting the semiconductor wafer.

The circuit layer 130 may be disposed on a front surface 110FS of the substrate 110 and may include an interlayer insulating layer 131 and an internal interconnection 132. The interlayer insulating layer 131 may include at least one of SiO, SiN, and SiON. The internal interconnection 132 may redistribute a rear pad 122 or a through-via 140 disposed on a rear surface 110BS and may be formed in a multilayer structure including a plurality of interconnection lines and a plurality of interconnection vias. The interconnection line and interconnection via may include a metal material (e.g., Al, Au, Co, Cu, Ni, Pb, Ta, Te, Ti, W, or a combination thereof. In some embodiments, a barrier film (not shown) (e.g., including Ti, TiN, Ta, TaN, or a combination thereof) may be disposed between the interconnection line and/or interconnection via and the interlayer insulating layer 131.

In some embodiments, the rear cover layer 120 may be disposed on a rear surface 110BS of the substrate 110 and may include a rear insulating layer 121 as a ‘first bonding insulating layer’ and a rear pad 122 as a ‘first bonding pad’. The rear insulating layer 121 and the front insulating layer 151 may include at least one of SiO. SiN, SiON, SiC, SiOC, and SiCN. The rear pad 122 and the front pad 152 may include the metal material described herein, similarly to the internal interconnection 132, but do not necessarily include the same type of metal material as the internal interconnection 132. The rear insulating layer 121 may include an insulating material that can be bonded to a second bonding insulating layer 221 of the semiconductor chip 200 (e.g., at least one of SiO. SiN. SiON, SiC, SiOC, and SiCN). From a similar point of view, the rear pad 122 may be formed of a conductive material that may be bonded to a second bonding pad 222 of the semiconductor chip 200 (e.g., at least one of Cu, Ni, Au, Ag, or alloys thereof). In some embodiments, the rear surface 110BS of the substrate 110 may be covered by a dielectric film (e.g., an ONO layer). The dielectric film may electrically insulate the rear pad 122 from a semiconductor material constituting the substrate 110.

In some embodiments, the circuit layer 130 may be disposed on a front surface 110FS of the substrate 110 and may include individual elements (not shown) constituting an integrated circuit. In this case, the internal interconnection 132 may be electrically connected to the individual elements (not shown). The individual elements may include various active and/or passive elements, such as FETs (e.g., planar FETs, FinFETs, or the like), memory devices (e.g., flash memories, DRAM, SRAM, EEPROM, PRAM, MRAM, FeRAM, and RRAM), logic devices (e.g., AND, OR, and NOT), and system LSI, CIS, and MEMS.

The front cover layer 150 may be disposed below the circuit layer 130. The front cover layer 150 may include a front insulating layer 151 and a front pad 152. The front pad 152 may be electrically connected to a rear pad 122 through the internal interconnection 132 and the through-via 140. The front pad 152 may provide a connection terminal through which the semiconductor structure 100 and the semiconductor chip 200 may be electrically connected to an external device. A separate connection member 159 (e.g., a solder ball, a copper pillar, etc.) may be disposed below the front pad 152, but the example embodiments of the present disclosure are not limited thereto. For example, the semiconductor structure 100 may be hybrid-bonded to another structure (e.g., a silicon interposer) without a connection member, such as a solder ball or the like.

The through-via 140 may penetrate through the substrate 110 and be electrically connected to the internal interconnection 132. The through-via 140 may be disposed to partially extend into a rear insulating layer 121 and into an interlayer insulating layer 131 of the circuit layer 130. In some embodiments, the through-via 140 may electrically connect individual elements (not shown) disposed on the front surface 110FS of the substrate 110 through the internal interconnection 132 of the circuit layer 130 and the internal interconnection 132. The through-via 140 may include a through electrode 141 and a barrier film 142, the barrier film 142 surrounding a side surface of the through electrode 141. The through electrode 141 may include, for example, W, Ti, Al, Cu, or a combination thereof. The barrier film 142 may include a metal compound, such as tungsten nitride (WN), TiN, TaN, or a combination thereof. In some embodiments, a via insulating film (not shown) may be formed on a side surface of the through-via 140. The via insulating film may be a single film or a multi-layered film. Additionally, the via insulating layer may include SiO, SiON, SiN, a polymer, or a combination thereof.

The semiconductor chip 200 may be stacked on the semiconductor structure 100 and may include a substrate 210, a circuit layer 230, and a second bonding structure 220. Although one semiconductor chip 200 is illustrated in the figures, the number of semiconductor chips 200 is not limited thereto in example embodiments of the present disclosure. For example, two or more semiconductor chips may be stacked in a vertical direction (e.g., Z-axis direction) or arranged in horizontal directions (e.g., X-axis and Y-axis directions) on the semiconductor structure 100. The substrate 210 and the circuit layer 230 may have similar characteristics to the substrate 110 and the circuit layer 130 of the semiconductor structure 100, and overlapping descriptions thereof will be omitted.

Some embodiments of the present disclosure may be described, for illustrative purposes, using directional information (e.g., although, in certain aspects, other implementations may be possible by analogy, without departing from the scope of the present disclosure). For instance, in some cases, a X-direction and a Y-direction may be referred to as horizontal directions (e.g., where the X-direction and the Y-direction may define a horizontal plane) and a Z-direction may be referred to as a vertical direction. In some cases, a vertical direction may refer to a direction perpendicular to a surface of the semiconductor chip 200 (e.g., where a surface of the semiconductor chip 200 may be parallel to a horizontal plane).

FIGS. 10A-10C are cross-sectional views illustrating a semiconductor device and a semiconductor package according to an example embodiment of the present disclosure. In some examples, the cross-sectional views illustrating a semiconductor device and a semiconductor package as described with reference to FIGS. 10A-10C may be implemented by aspects of or may implement aspects as described with reference to FIGS. 1-9E.

Referring to FIG. 10A, a semiconductor package 1000A according to an example embodiment may have the same or similar characteristics to those described with reference to FIGS. 9A to 9E except that a semiconductor chip 200 is provided with chiplets 200c11 and 200c12 disposed side by side on a semiconductor structure 100. In some embodiments, the semiconductor structure 100 and the semiconductor chip 200 may be mounted on a package substrate 300.

The chiplets 200c11 and 200c12 may mean each chip constituting an MCM. The MCM can be composed of I/O, a central processor unit (CPU), a graphic processor unit (GPU), field programmable gate array (FPGA) chips, and the like. The number of chiplets stacked on the semiconductor structure 100 is not particularly limited, and, for example, two or less chiplets or four or more chiplets may be mounted on the semiconductor structure 100. In some embodiments, the chiplet or chiplet technology may refer to a semiconductor chip manufactured separately according to the size and function of a device or a manufacturing technology of such a semiconductor chip.

In some embodiments, the semiconductor structure 100 may be, for example, an active interposer performing a function of an I/O chip. The semiconductor chip 100 may include an I/O device, a DC/DC converter, a sensor, a test circuit, and the like, therein. Accordingly, the chiplets 200c11 and 200c12 and the semiconductor structure 100 may constitute an MCM.

In the figures, the semiconductor structure 100 may be mounted on the package substrate 300 through a connection member 159. However, depending on the type of the base substrate 300 (e.g., silicon substrate), a front cover layer 150 may form hybrid bonding with the package substrate 300. For example, because an edge portion of the front cover layer 150 is cut through the manufacturing process as described with reference to FIGS. 4A-9E, a burr formed on a front insulating layer 151 of the front cover layer 150 may be removed, and the front cover layer 150 may include a flat bonding surface without irregularities.

For example, the package substrate 300 may include a lower pad 312 disposed on a lower surface of a body, an upper pad disposed on an upper surface of the body, and a redistribution circuit 313 electrically connecting the lower pad 312 and the upper pad 311. The package substrate 300 may be a substrate for a semiconductor package including a printed circuit board (PCB), a ceramic substrate, a glass substrate, a tape interconnection board, and the like. The body of the package substrate 300 may include different materials depending on the type of substrate. For example, when the package substrate 300 is a PCB, it may have a form in which an interconnection layer is additionally stacked on one or both surfaces of a body copper-clad laminate or a copper-clad laminate. A solder resist layer may be formed on the lower surface and the upper surface of the package substrate 300, respectively. The upper pads 311, the lower pads 312, and the redistribution circuit 313 may form an electrical path connecting the lower surface and the upper surface of the package substrate 300. An external connection terminal 320 connected to the lower pad 312 may be disposed below the package substrate 300. The external connection terminal 320 may be formed of a conductive material having a shape such as a ball or a pin.

Referring to FIG. 10B, a semiconductor package 1000B according to an example embodiment of the present disclosure may have the same or similar features as those described with reference to FIG. 9E, except that a semiconductor chip on the semiconductor structure 100 is provided as a plurality of semiconductor chips 200A, 200B1, 200B2, and 200C. The semiconductor package 1000B may further include an encapsulant 260 covering the plurality of semiconductor chips 200A, 200B1, 200B2, and 200C on the semiconductor structure 100. The encapsulant 260 may expose an upper surface of the third semiconductor chip 200C. Additionally, the encapsulant 260 may cover the upper surface of the third semiconductor chip 200C according to example embodiments. The encapsulant 260 may include, for example, an epoxy mold compound (EMC), but a material of the encapsulant 260 is not particularly limited. The number of the plurality of semiconductor chips 200A, 200B1, 200B2, and 200C is not limited to that shown in the figures, and may be two, three, or five or more. In some embodiments, the encapsulant 260 may contact a burr.

The plurality of semiconductor chips 200A, 200B1, 200B2, and 200C may include a first semiconductor chip 200A attached to an upper surface of the semiconductor structure 100, one or more second semiconductor chips 200B1 and 200B2 sequentially stacked on the first semiconductor chip 200A, and a third semiconductor chip 200C stacked on the second semiconductor chips 200B1 and 200B2. Each of the first to third semiconductor chips 200A, 200B1, 200B2, and 200C may include a structure such as a second bonding structure 220, and a hybrid bonding structure may be formed between the first semiconductor chip 200A and the semiconductor structure 100 and between the second semiconductor chips 200B1 and 200B2 and the third semiconductor chip 200C. Because the second bonding structure 220 is formed through the manufacturing process as described with reference to FIGS. 4A-9E, burrs may be removed to include a flat bonding surface without irregularities. In some embodiments, the first semiconductor chip 200A and the second semiconductor chips 200B1 and 200B2 may further include a second through-via 240. The second through-via 240 may include a through electrode 241 and a barrier film 242. The through electrode 241 and the barrier film 242 of the second through-via 240 may have characteristics similar to those of the through electrode 141 and the barrier film 142 of FIGS. 9A-9E, and overlapping descriptions thereof are omitted.

As an example, the semiconductor structure 100 may be a buffer chip including a plurality of logic devices and/or memory devices. Additionally, the semiconductor structure 100 may transmit a signal from a plurality of semiconductor chips 200A, 200B1, 200B2, and 200C, stacked thereabove externally, and also may transmit a signal and power from the outside to the plurality of semiconductor chips 200A, 200B1, 200B2, and 200C. The semiconductor structure 100 may perform both a logic function and a memory function through logic devices and memory devices but may include only logic elements and perform only a logic function according to example embodiments. The plurality of semiconductor chips 200A, 200B1, 200B2, and 200C may include, for example, volatile memory chips (e.g., DRAM, SRAM, etc.) or non-volatile memory chips (e.g., PRAM, MRAM, FeRAM, RRAM, etc.). As an example, the semiconductor package 1000B of this embodiment may be used for a High Bandwidth Memory (HBM) product or an Electro Data Processing (EDP) product.

Referring to FIG. 10C, a semiconductor package 1000C according to an example embodiment of the present disclosure may have the same or similar features as those described with reference to FIGS. 9A-9E, except for further including a package substrate 300 on which a semiconductor structure 100 is mounted and an encapsulant 260 for encapsulating the semiconductor structure 100 and the semiconductor chip 200 on the package substrate 300.

The semiconductor structure 100 may include, for example, a CPU, a GPU, an FPGA, an application processor (AP), a digital signal processor (DSP), a cryptographic processor, a microprocessor, a microcontroller, an analog-to-digital converter, and a logic chip such as an application specific integrated circuit (ASIC), and the like. In addition, the semiconductor chip 200 may include a memory chip such as DRAM, SRAM, PRAM, MRAM, FeRAM, or RRAM. In the present embodiment, the semiconductor chip 200 is illustrated in the same manner as in FIGS. 9A-9E, but may have a shape similar to that described with reference to FIGS. 10A-10C. For example, the semiconductor chip 200 may include a Power Management IC (PMIC) chip.

As set forth herein, according to an example embodiment of the present disclosure, in a semiconductor device, a semiconductor package and a method of manufacturing a semiconductor chip, bonding characteristics of a front surface of the semiconductor chip or bonding characteristics between the plurality of semiconductor chips may be improved, so that electrical characteristics and/or reliability of the front surface of the semiconductor chip and between the plurality of semiconductor chips may be improved.

While example embodiments have been shown and described herein, it will be apparent to those skilled in the art that modifications and variations could be made without departing from the scope of the present disclosure as defined by the appended claims.

What is claimed is:

1. A semiconductor device, comprising:
a substrate;
one or more front pads disposed on a front surface of the substrate; and
a circuit layer comprising an insulating layer and at least one interconnection electrically connected to the one or more front pads, the insulating layer disposed between the one or more front pads and the substrate,
wherein a side surface of the circuit layer comprises a burr, the burr protruding a height that is below a level of a front surface of the circuit layer, or the burr forming a step portion in the circuit layer, or a combination thereof.

2. The semiconductor device of claim 1, wherein the circuit layer comprises a first edge between the front surface of the circuit layer and the side surface of the circuit layer and a second edge formed by the burr,
wherein the burr is more curved than the first edge.

3. The semiconductor device of claim 1, wherein the burr has a gentler slope than a region in which the burr is not disposed on the side surface of the circuit layer.

4. The semiconductor device of claim 1, wherein the burr is disposed on a step portion on the side surface of the circuit layer or forms the step portion.

5. The semiconductor device of claim 4, wherein the step portion on the side surface of the circuit layer provides an additional front surface of the circuit layer,
wherein the burr protrudes convexly from the additional front surface.

6. The semiconductor device of claim 1, wherein the burr comprises a mixed material, the mixed material comprising at least one of a material of the interconnection and a material of the substrate mixed with an insulating material of the insulating layer.

7. The semiconductor device of claim 6, wherein the insulating material of the insulating layer comprises at least one of a silicon oxide, silicon nitride, silicon oxynitride, or a combination thereof.

8. The semiconductor device of claim 1, wherein a density of the burr is lower than a density of the insulating layer.

9. The semiconductor device of claim 1, wherein the substrate comprises a recessed portion recessed between the substrate and the circuit layer.

10. The semiconductor device of claim 1, further comprising:
a bonding insulating layer disposed on the front surface of the circuit layer and surrounding the one or more front pads,
wherein the burr is spaced apart from the bonding insulating layer.

11. A semiconductor package, comprising:
a plurality of semiconductor chips, wherein each of the semiconductor chips comprises:
a substrate;
one or more front pads disposed on a front surface of the substrate; and
a circuit layer comprising an insulating layer and at least one interconnection electrically connected to the one or more front pads, the insulating layer disposed between the one or more front pads and the substrate,
wherein one of the plurality of semiconductor chips further comprises a bonding insulating layer disposed on a front surface of the circuit layer and surrounding the one or more front pads,
wherein the other of the plurality of semiconductor chips further comprise one or more rear pads and bonding insulating layers, the one or more rear pads disposed on a rear surface of the substrate and the bonding insulating layers disposed on a rear surface of the substrate and surrounding the one or more rear pads,
wherein the plurality of semiconductor chips is bonded to each other through the bonding insulating layers, and
wherein a side surface of the circuit layer of at least one of the plurality of semiconductor chips has a portion, the portion protruding while being spaced apart from the bonding insulating layer, or the portion forming a step portion in the circuit layer, or a combination thereof.

12. The semiconductor package of claim 11, wherein the circuit layer of at least one of the plurality of semiconductor chips comprises a first edge between the front surface of the circuit layer and the side surface of the circuit layer and a second edge protruding from the side surface of the circuit layer or forming a step portion,
wherein the second edge is more curved than the first edge.

13. The semiconductor package of claim 11, wherein the portion protruding from the side surface of the circuit layer or forming the step portion comprises a gentler slope than a remaining region of the side surface of the circuit layer.

14. The semiconductor package of claim 11, wherein the portion protruding from the side surface of the circuit layer or forming the step portion comprises a mixed material, the mixed material comprising at least one of a material of the interconnection and a material of the substrate mixed with an insulating material of the insulating layer.

15. The semiconductor package of claim 11, further comprising:
an encapsulant encapsulating the plurality of semiconductor chips, wherein the portion protruding from the side surface of the circuit layer or forming the step portion is in contact with the encapsulant.

16. The semiconductor package of claim 11, wherein the substrate of at least one of the plurality of semiconductor chips comprises a recessed portion recessed between the substrate and the circuit layer.

17. A method of manufacturing a semiconductor chip, comprising:
forming a mask layer on a wafer, the wafer comprising a substrate and an insulating layer,
etching, using a laser grooving process and a plasma process, a portion of the insulating layer so that the insulating layer is separated into a plurality of insulating layers; and
etching a portion of the substrate so that the substrate is separated into a plurality of substrates,
wherein etching the portion of the insulating layer comprises performing the plasma process so that a burr according to the laser grooving process protrudes a height that is below a level of front surfaces of the plurality of insulating layers.

18. The method of claim 17, wherein the plasma process comprises a first plasma process using an O₂ plasma gas and a second plasma process performed after the first plasma process, the second plasma process using a CₓF_{y} or CHₓF_{y} plasma gas.

19. The method of claim 17, wherein the plasma process comprises forming a trench in the insulating layer using a CₓF_{y} or CHₓF_{y} plasma gas,
wherein the laser grooving process is performed after the formation of the trench.

20. The method of claim 17, wherein forming the mask layer comprises:
forming a first mask layer on the wafer, the wafer comprising the substrate and the insulating layer;
removing the first mask layer; and
forming a second mask layer on the wafer comprising the substrate and the insulating layer,
wherein the plasma process comprises forming a trench in the insulating layer using a CₓF_{y} or CHₓF_{y} plasma gas in a state in which the first mask layer is formed.
